(19) United States
(12) Patent Application Publication
(10) Pub. No.: US 2012/0037225 A1
(43) Pub. Date: Feb. 16, 2012

(54) SOLAR CELL AND METHOD OF FABRICATING THE SAME

(75) Inventors: Suk Jae Jee, Seoul (KR); Ho Gun Cho, Seoul (KR); Chul Hwan Choi, Seoul (KR)

(73) Assignee: LG INNOTEK CO., LTD., Seoul (KR)

(21) Appl. No.: 13/266,588

(22) PCT Filed: Jun. 16, 2010
(86) PCT No.: PCT/KR10/03889

§ 371 Date: Oct. 27, 2011

(30) Foreign Application Priority Data
Jun. 16, 2009 (KR) 10-2009-0053230
Jun. 19, 2009 (KR) 10-2009-0054724

(51) Int. Cl. H01L 31/0224; H01L 31/18

(52) U.S. Cl. 136/256; 438/98; 257/E31.124

(57) ABSTRACT

Disclosed are a solar cell and a method of fabricating the same. The solar cell includes a substrate, a rear electrode layer provided on the substrate, a light absorbing layer provided on the rear electrode layer, and a front electrode layer provided on the light absorbing layer, wherein the front electrode layer includes, a first conductive layer provided on the light absorbing layer, and a second conductive layer provided on the first conductive layer.

### TECHNICAL FIELD

The embodiment relates to a solar cell and a method of fabricating the same.

### BACKGROUND ART

Recently, as demand for energy is increased, a solar cell has been developed to convert solar energy into electrical energy.

Especially, a CIGS-based solar cell serving as a PN hetero junction device has been extensively used. The CIGS-based solar cell has a substrate structure including a glass substrate, a metal rear surface electrode layer, a P type CIGS-based light absorbing layer, a high resistant buffer layer, and an N type window layer.

Such a solar cell can represent improved efficiency due to electrical characteristics such as low resistance and high transmittance.

### DISCLOSURE OF INVENTION

### Technical Problem

The embodiment provides a solar cell having improved performance and a method of fabricating the same.

### Solution to Problem

According to the embodiment, a solar cell includes a substrate, a rear electrode layer provided on the substrate, a light absorbing layer provided on the rear electrode layer, and a front electrode layer provided on the light absorbing layer, wherein the front electrode layer includes, a first conductive layer provided on the light absorbing layer, and a second conductive layer provided on the first conductive layer.

According to the embodiment, a solar cell includes a substrate, a rear electrode layer provided on the substrate, a light absorbing layer provided on the rear electrode layer, and a plurality of conductive layers provided on the light absorbing layer. The conductive layers include identical material, and adjacent conductive layers have grain sizes different from each other.

According to the embodiment, a method of fabricating a solar cell including forming a rear electrode layer on a substrate, forming a light absorbing layer on the rear electrode layer, forming a first conductive layer on the light absorbing layer using first power, and forming a second conductive layer on the first conductive layer using second power.

### Advantageous Effects of Invention

The solar cell according to the embodiment includes the front electrode layer having a multiple structure. In other words, the front electrode layer includes conductive layers having characteristics different from each other.

Accordingly, the conductive layers compensate each other for inferior characteristics, so that the characteristic of the front electrode layer can be improved. For example, the first conductive layer has a dense structure, and the second conductive layer has high conductivity.

Accordingly, the mechanical characteristic of the front electrode layer can be improved due to the first conductive layer, and the electrical characteristic of the front electrode layer can be improved due to the second conductive layer. In more detail, the first conductive layer compensates for the mechanical characteristic of the second conductive layer, and the second conductive layer compensates for the electrical characteristic of the first conductive layer. Accordingly, the front electrode can have improved mechanical and electrical characteristics.

The lowermost layer of the front electrode layer can have a dense structure, so that the impurities of the front electrode layer can be easily prevented from being diffused into a light absorbing layer.

Accordingly, the whole characteristic of the solar cell according to the embodiment can be improved.

### BRIEF DESCRIPTION OF DRAWINGS

FIGS. 1 to 8 are sectional views showing a method of fabricating a solar cell according to a first embodiment;

FIG. 9 is a sectional view schematically showing a sputtering device to form a front electrode layer according to the first embodiment; and

FIGS. 10 to 13 are sectional views showing a method of fabricating a solar cell according to the second embodiment.

### MODE FOR THE INVENTION

In the description of an embodiment, it will be understood that, when a substrate, a layer, a film, or an electrode is referred to as being “on” or “under” another substrate, another layer, another film, or another electrode, it can be “directly” or “indirectly” on the other substrate, layer, film, electrode or one or more intervening layers may also be present. Further, “on” or “under” of each layer is determined based on the drawing. Further, “on” or “under” of each layer is determined based on the drawing. The thickness or size of layers shown in the drawings can be simplified or exaggerated for the purpose of clear explanation. In addition, the size of each element may be reduced or magnified from the real size thereof.

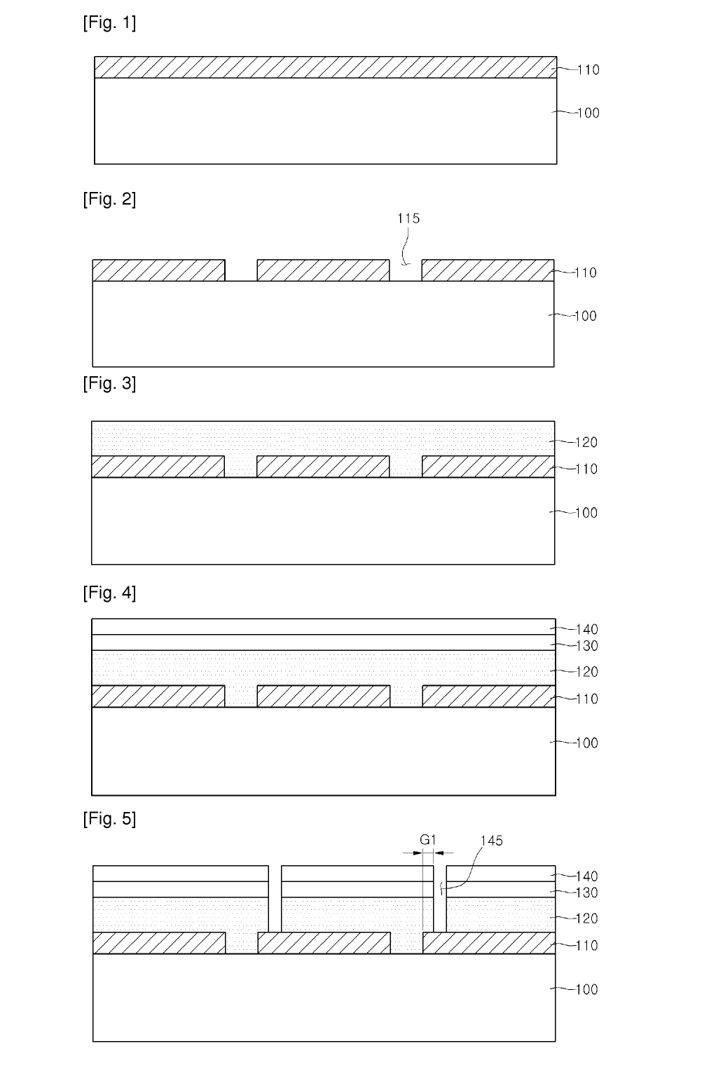

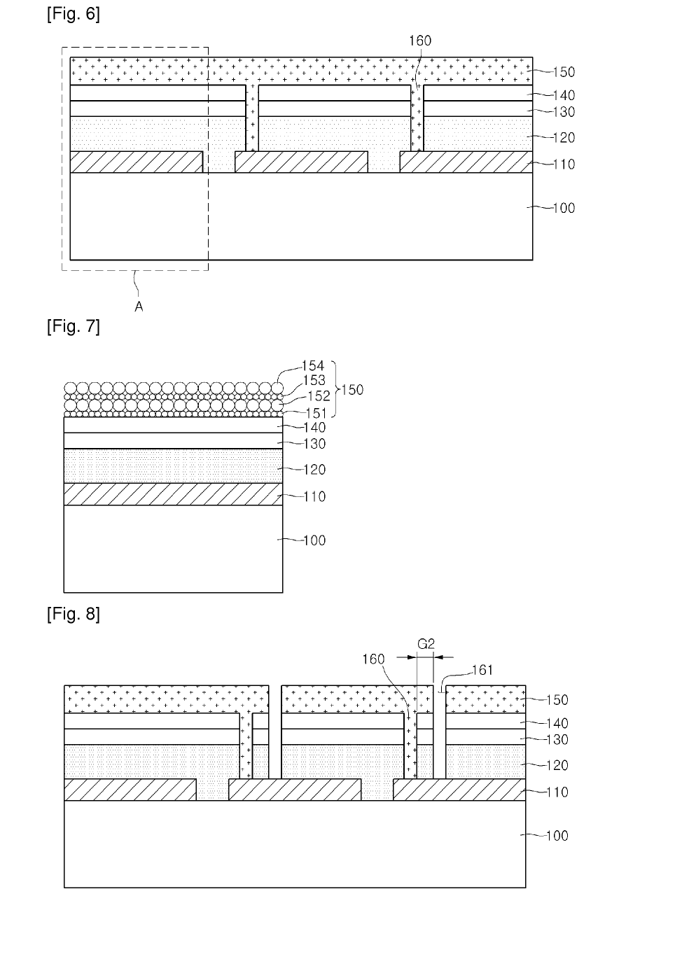

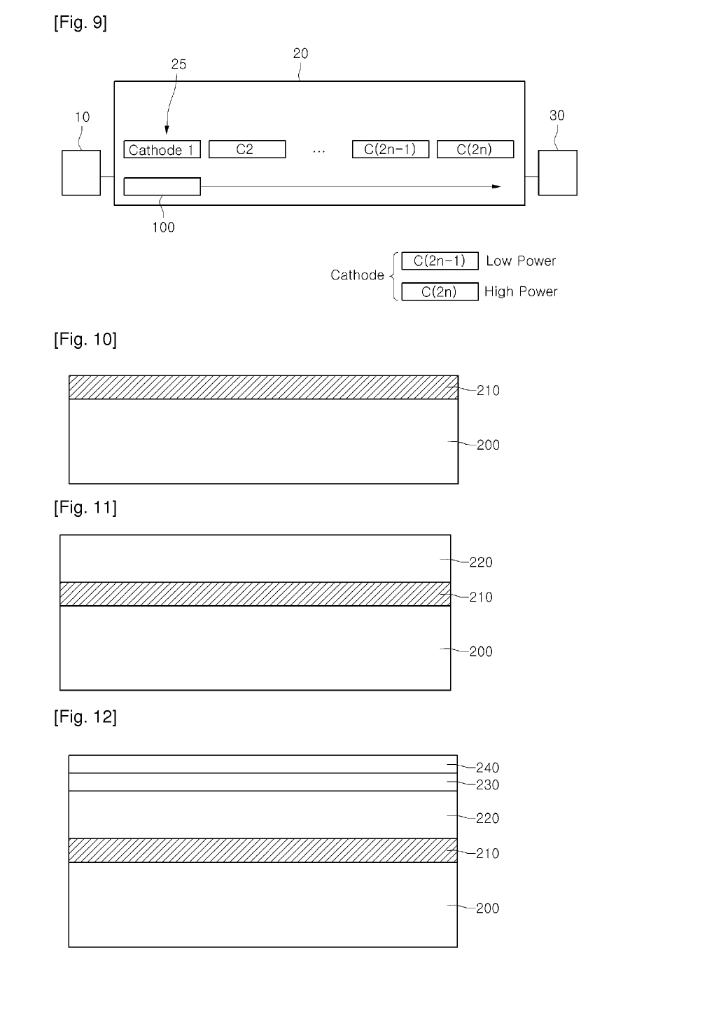

FIGS. 1 to 9 are sectional views showing a method of fabricating a solar cell according to a first embodiment. FIG. 7 is an enlarged sectional view showing a front electrode layer in a region A of FIG. 6. FIG. 9 is a view schematically showing a sputtering device to form the front electrode layer of FIG. 6.

Referring to FIG. 1, a rear electrode layer 110 is formed on a substrate 100.

The substrate 100 includes an insulator, and may be rigid or flexible. The substrate 100 may include glass, ceramic, metal, or polymer. For example, the glass substrate 100 may include sodalime glass or high strained point soda glass.

The rear electrode layer 110 may include a conductor made of metal. The rear electrode layer 110 includes metal to improve series resistance characteristics and increase electrical conductivity. For example, the rear electrode layer 110 may have a thickness in the range of about 500 nm to about 1500 nm.

For example, the rear electrode layer 110 may be formed through a sputtering process using a Mo target. This is because Mo represents high conductivity, an ohmic contact characteristic with a light absorption layer, and high temperature stability at a Se (selenium) atmosphere.

The Mo thin film constituting the rear electrode layer 110 must have low resistivity in order to act as an electrode, and must have a superior adhesion property with the substrate 100 such that delamination caused by the difference in a thermal expansion coefficient does not occur. Meanwhile, the material of the rear electrode layer 110 is not limited thereto, but may be Mo doped with sodium (Na) ions.

Although not shown in FIG. 1, the rear electrode layer 110 may include at least one layer. When the rear electrode layer 110 includes a plurality of layers, the layers of the rear electrode layer 110 may include materials different from each other.

Referring to FIG. 2, the rear electrode layer 110 is patterned, so that plurality of rear electrodes are formed. The rear electrode layer 110 may be divided into separate sections by first grooves 115. The first grooves 115 selectively expose a top surface of the substrate 100.

The first grooves 115 may be patterned through a laser scribing process. For example, the width of each first groove 115 may be in the range of about 50 μm to about 70 μm.

The rear electrodes may have the form of a stripe or a matrix by the first grooves 115.

Referring to FIG. 3, a light absorbing layer 120 is formed on the rear electrode layer 110.

The light absorbing layer 120 includes Ib-IIIb-VIb-based compound.

In more detail, the light absorbing layer 120 may include Cu—In—Ga—Se₂ (CIGS)-based compound or Cu—In—Se₂ (CIS)-based compound.

For example, in order to form the light absorbing layer 120, a CIG-based metal precursor layer is formed on the rear electrode layer 110 by using a Cu target, an In target, and a Ga target.

Thereafter, the metal precursor layer reacts with Se through a selenization process, thereby forming a CIGS-based light absorbing layer 120.

The light absorbing layer 120 may be formed through a co-evaporation process using Cu, In, Ga, and Se.

For example, the light absorbing layer 120 may be formed at the thickness of about 1000 nm to about 3000 nm.

The light absorbing layer 120 receives external light and converts the external light into electrical energy. The light absorbing layer 120 generates photoelectro-motive force due to a photovoltaic effect.

Referring to FIG. 4, a buffer layer 130 and a high-resistance buffer layer 140 are formed on the light absorbing layer 120.

The buffer layer 130 may include at least one layer on the light absorbing layer 120.

The buffer layer 130 may be formed by stacking cadmium sulfide (CdS). For example, the buffer layer 130 may have a thickness of about 30 nm to about 70 nm.

In this case, the buffer layer 130 is an N-type semiconductor layer, and the light absorbing layer 120 is a P-type semiconductor layer. Accordingly, the light absorbing layer 120 and the buffer layer 130 form a PN junction.

The high resistance layer 140 may be formed through a sputtering process employing a zinc oxide (ZnO) target. In other words, a ZnO layer may be additionally formed on the CdS layer.

The high resistance buffer layer 140 may be provided in the form of a transparent layer on the buffer layer 130. For example, the high resistance buffer layer 140 may include one of indium tin oxide (ITO), zinc oxide (ZnO), and intrinsic zinc oxide (i-ZnO). The high resistance buffer layer 140 may have a thickness in the range of about 30 nm to about 70 nm.

The buffer layer 130 and the high resistance buffer layer 140 are interposed between the light absorbing layer 120 and the front electrode layer 150 that is formed in the following process.

In other words, since the light absorbing layer 130 and the front electrode layer 150 have great difference therebetween in a lattice constant and an energy band gap, superior junction can be obtained between the light absorbing layer 130 and the front electrode layer if the buffer layer 130 and the high resistance buffer layer 140 having the intermediate band gap are interposed between the light absorbing layer 130 and the front electrode layer

According to the embodiment, two buffer layers 130 and 140 are formed on the light absorbing layer 120, but the embodiment is not limited thereto. In this case, the buffer layers 130 and 140 may be integrated into one buffer layer, and at least three buffer layers may be formed.

Referring to FIG. 5, contact patterns 145 passing through the light absorbing layer 120, the buffer layer 130, and the high resistance buffer layer 140 are formed.

Each contact pattern 145 is adjacent to the first groove 115, and exposes a portion of the rear electrode.

The contact pattern 145 may be formed by a mechanical device such as a tip.

For example, the contact pattern 145 may have a width in the range of about 60 μm to about 100 μm. In addition, a gap G1 between the contact pattern 145 and the first groove 115 may be in the range of about 60 μm to about 100 μm.

Referring to FIGS. 6 and 7, a front electrode layer 150 is formed on the high resistance buffer layer 140. The material of the front electrode layer 150 is filled in the contact pattern 145, and a connection part 160 may be formed in the contact pattern 145.

Accordingly, the rear electrode is electrically connected to the front electrode layer 150 by the connection part 160.

As shown in FIG. 7, the front electrode layer 150 may include a plurality of conductive layers. In other words, the front electrode layer 150 may have a stack structure of the conductive layers. At least three conductive layers may be provided. In more detail, three to ten conductive layers may be provided.

For example, the front electrode layer 150 may include a first conductive layer 151, a second conductive layer 152, a third conductive layer 153, and a fourth conductive layer 154. Although not shown in FIG. 7, additional conductive layers, for example, fifth to tenth conductive layers may be further stacked on the fourth conductive layer 154.

The first conductive layer 151 is provided on the high resistance buffer layer 140.

The second buffer layer 152 is provided on the first conductive layer 151. The third conductive layer 153 is provided on the second conductive layer 152. The fourth conductive layer 154 is provided on the third conductive layer 153.

The first to fourth conductive layers 151 to 154 include the same material. In more detail, the first to fourth conductive layers 151 to 154 consist of the same material. For example, the first to fourth conductive layers 151 to 154 may include ZnO or ITO doped with impurities such as aluminum (Al), alumina (Al₂O₃), magnesium (Mg), and gallium (Ga).

The first to fourth conductive layers 151 to 154 may have grain sizes different from each other. For example, adjacent conductive layers among the first to fourth conductive layers 151 to 154 have different grain sizes. Since the adjacent conductive layers are formed under different process conditions, the grains of the adjacent conductive layers may have different sizes. In detail, the adjacent conductive layers may be formed through sputtering process employing cathodes to receive different power. Accordingly, the grains of the adjacent conductive layers may have different sizes.

For example, although the first and second conductive layers 151 and 152 may include the same material, the first and second conductive layers 151 and 152 have different grain sizes. The grain size of the first conductive layer 151 may be smaller. In addition, the grain size of the second conductive layer 152 may be greater. In this case, the grain sizes of the first and second conductive layers 111 and 112 may have the ratio of about 1:1.25 to 1:2.

Accordingly, the first conductive layer 151 has a dense film structure having higher density, and may have a high mechanical characteristic. In contrast, although the second conductive layer 152 is a film having lower density, the second conductive layer 112 may have high conductivity and transmittance.

Similarly, the third conductive layer 153 has a grain size different from that of the second conductive layer 152. In other words, the grain size of the third conductive layer 153 may be smaller than the grain size of the second conductive layer 152.

In addition, the fourth conductive layer 154 has a grain size different from that of the third conductive layer 153. In other words, the grain size of the fourth conductive layer 154 may be greater than the grain size of the third conductive layer 153.

Since the adjacent conductive layers have grain sizes different from each other, the adjacent conductive layers may have electrical and mechanical properties different from each other. For example, the adjacent conductive layers may have different conductivities, different mechanical strengths, or different refractive indexes.

In the front electrode layer 150, the conductive layers 151 and 153 having smaller grain sizes and the conductive layers 152 and 154 having greater grain sizes are alternately stacked on each other.

For example, the grain size of the first conductive layer 151 may correspond to the grain size of the third conductive layer 153. In addition, the grain size of the second conductive layer 152 may correspond to the grain size of the fourth conductive layer 154.

The grain sizes of the first and third conductive layers 151 and 153 may be in the range of about 15 nm to about 20 nm, and the grain sizes of the second and fourth conductive layers 152 and 154 may be in the range of about 30 nm to about 40 nm. In addition, the first and third conductive layers 151 and 153 may have a thickness in the range of about 15 nm to about 40 nm. The second and fourth conductive layers 152 and 154 may have the thickness in the range of about 30 nm to about 80 nm.

In other words, the front electrode layer 150 is a window layer forming a PN junction with the light absorbing layer 120. The front electrode layer 150 acts as a transparent electrode at a front surface of the solar cell, the front electrode layer 150 includes ZnO representing high light transmission and high electrical conductivity.

For example, the first to fourth conductive layers 151 to 154 may constitute an electrode having a low resistance value formed by forming ZnO doped with Al or Al₂O 3 through a sputtering process.

In particular, the conductive layers 151 to 154 may be formed through one sputtering process in the same chamber.

In detail, referring to FIG. 9, the sputtering device to form the first to fourth conductive layers 151 to 154 may include a loading chamber 10 to receive the substrate 100, a process chamber 20 to deposit a thin film on the substrate 100, and an unloading chamber 30 to discharge the substrate 100.

The process chamber 20 includes a plurality of cathodes 25. The cathodes 25 includes cathodes C(2n−1) to receive low power and cathodes C(2n) to receive high power. In detail, the cathodes C(2n−1) to receive the low power and the cathodes C(2n) to receive high power are alternate aligned with each other.

According to the operation of the sputtering device, when the substrate 100 introduced into the process chamber 20 by the loading chamber 10 sequentially passes through first and second cathodes C1 and C2 such that the first to fourth conductive layers 151 to 154 may be formed.

In other words, since the substrate 100 sequentially moves below the low-power cathodes C(2n−1) and the high-power cathodes C(2n), the front electrode layer 150 may be formed in the contact patter 145 and on the high resistance buffer layer 140 due to different power.

For examples, the process chamber 20 is maintained at a normal temperature of 1° C. to 30° C. under at an internal pressure of about 1 mTorr to 10 mTorr. The low-power cathodes C(2n−1) receives power of about 1 kW/cm² to about 2 kW/cm². The high-power cathodes C(2n) can receive power of about 4 kW/cd to about 10 kW/cd.

Accordingly, the first conductive layer 151 is deposited on the substrate 100 passing through the lower portion of the first cathode C1. For example, the first conductive layer 151 may have an average grain size of about 15 nm to about 20 nm.

The first conductive layer 151 may be formed by depositing a target material in small grain size at a high density by the cathode C1 to receive low power. Accordingly, the first conductive layer 151 can improve the adhesion strength and the light transmittance with the high resistance buffer layer 140.

In addition, the first conductive layer 151 is formed in a normal-temperature process, and has a dense structure, thereby preventing Al ions from being diffused into the high resistance buffer layer 140.

The second conductive layer 152 is formed on the substrate 100 passing through the second cathode C2. A target material is deposited on the first conductive layer 151 through the second cathode C2 such that the second conductive layer 152 is formed. For example, the grain size of the second conductive layer 152 may be in the range of about 30 nm to about 40 nm.

The atoms of the target material are deposited on the first conductive layer 151 at a high deposition rate by the second cathode C2 into which high power has been applied, so that the second conductive layer 152 may have a grain size greater than that of the first conductive layer 151. Accordingly, the second conductive layer 152 may have improved conductivity.

In addition, the second conductive layer 152 is formed in a normal temperature process to prevent Al ions from being diffused into the high resistance buffer layer 140. Accordingly, the insulating property of the high resistance buffer layer 140 can be maintained, and the surface resistance characteristic of the front electrode layer 150 can be improved.

Similarly, the third and fourth conductive layers 153 and 154 may be additionally formed by the cathodes 25. For example, third to tenth conductive layers may be formed. Therefore, the conductive layers 151 and 153 formed by the low-power cathodes C(2n−1) can be filled in voids of the conductive layers 152 and 154 formed by the high-power cathodes C(2n).

Hereinafter, the operation of the process chamber will be described in more detail. If power is applied to the process chamber, reaction gas collides with electrons emitted from the cathodes 25 so that the reaction gas is excited and changed into ions. The ions are drawn to the cathodes 25 and collide with a target used to form a layer. In this case, ion particles have energy, and the energy is transited to the target used to form the layer when the ions collide with the target. When the transited energy overcomes the bond strength and a work function of elements constituting the target, plasma is discharged, and particles of target materials are stacked on the substrate 100.

In this case, targets placed corresponding to the cathodes 25 may include the same material, for example, Al doped ZnO. In other words, the targets include the same material, such as the Al doped ZnO, to form the conductive layers 151 to 154.

Differently from the drawing, the apparatus of fabricating the solar cell according to the embodiment includes the first cathodes to receive low power and the second cathodes to receive high power, and the substrate 100 may reciprocate below the first and second cathodes at least two times. Accordingly, the front electrode layer 150 including at least four conductive layers may be formed on the high resistance buffer layer 140.

As described above, the front electrode layer 150 includes the first to fourth conductive layers 151, 152, 153, and 154, so that all of adhesion strength, surface resistance, and light transmittance can be ensured. In other words, since the conductive layers 151, 152, 153, and 154 are stacked on each other by alternately applying low power and high power, both of adhesion strength and light transmittance can be improved.

In addition, since the first to fourth conductive layers 151 to 154 are formed by repeatedly applying different power, the conductive layers 151 to 154 can be densely formed and the crystalline property can be improved. Accordingly, the conductivity of the conductive layers can be improved.

In addition, the conductive layers 151 to 154 are formed at a normal-temperature-process, so that Al ions, which are conductive impurities, can be prevented from being diffused into another layer. Accordingly, shut current is blocked, so that the electrical characteristic of the solar cell can be improved.

Referring to FIG. 8, a second groove 161 is formed through the front electrode layer 150, the high resistance buffer layer 140, the buffer layer 130, and the light absorbing layer 120. The second groove 161 exposes a portion of the rear electrode.

The second groove 161 may be adjacent to the contact part 160. The second groove 161 may be patterned by a mechanical device or a laser. For example, the second groove 161 may have a width in the range of about 60 μm to about 100 μm. The gap G2 between the connection part 160 and the second groove 161 may be in the range of about 60 μm to about 100 μm. The front electrode layer 150 is patterned so that a plurality of front electrodes and a plurality of cells may be defined.

The front electrode layer 150 includes the conductive layers 151, 152, 153, and 154 having different grain sizes. Accordingly, the conductive layers 151, 152, 153, and 154 have mechanical, optical, and electrical characteristics different from each other.

The conductive layers 151 and 153 having smaller grain sizes can improve the mechanical characteristic of the front electrode layer 150. In addition, the conductive layers 152 and 154 having greater grain sizes can improve the electrical characteristic of the front electrode layer 150.

In addition, since the refractive indexes vary depending on grain sizes, the front electrode layer 150 has a structure in which conductive layers having higher or lower refractive indexes are alternately stacked on each other. Therefore, the front electrode layer 150 has improved light transmittance.

As described above, the solar cell including the front electrode layer 150 having improved mechanical, optical, and electrical characteristics may be easily provided.

FIGS. 10 to 13 are sectional views showing a method of fabricating a solar cell according to the second embodiment. Hereinafter, the second embodiment will be described while referring to description about the solar cell and the method of fabricating the same according to the first embodiment. In other words, the description of the second embodiment is identical to that of the first embodiment except for description about components added or modified in the second embodiments.

Referring to FIG. 10, a rear electrode layer 210 is formed on a substrate 200. The substrate may include glass, ceramic, metal, or polymer. For example, the glass substrate 200 may include sodalime glass or high strained point soda glass.

The substrate 200 may be transparent. The substrate 200 may be rigid or flexible.

The rear electrode layer 210 may serve as a conductor including metal. For example, the rear electrode layer 210 may be formed through a sputtering process employing an Mo target. Meanwhile, the material of the rear electrode layer 210 is not limited thereto, but may include Mo doped with Na.

This is because Mo represents high conductivity, an ohmic contact characteristic with a light absorption layer, and high temperature stability at a selenium (Se) atmosphere. The Mo thin film constituting the rear electrode layer 210 must have low resistivity in order to act as an electrode, and must have a superior adhesion property with the substrate 200 such that delamination caused by the difference in a thermal expansion coefficient does not occur. The rear electrode layer 210 may include at least one layer. When the rear electrode layer 210 includes a plurality of layers, the layers constituting the rear electrode layer 210 may include different materials.

Referring to FIG. 11, a light absorbing layer 220 is formed on the rear electrode layer 210. The light absorbing layer 220 includes Ib-IIIb-VIb-based compound. In more detail, the light absorbing layer 220 may include Cu—In—Ga—Se₂ (GIGS)-based compound or Cu—In—Se₂ (CIS)-based compound.

For example, in order to form the light absorbing layer 220, a CIG-based metal precursor layer is formed on the rear electrode layer 210 by using a Cu target, an In target, and a Ga target.

Thereafter, the metal precursor layer reacts with Se through a selenization process, thereby forming a CIGS-based light absorbing layer 220. The light absorbing layer 220 may be formed through a co-evaporation process using Cu, In, Ga, and Se. The light absorbing layer 220 receives external light and converts the external light into electrical energy. The light absorbing layer 220 generates photoelectro-motive force due to a photovoltaic effect.

Referring to FIG. 12, a buffer layer 230 and a high-resistance buffer layer 240 are formed on the light absorbing layer 220.

The buffer layer 230 may include at least one layer formed on the light absorbing layer 220. The buffer layer 230 may be formed by stacking cadmium sulfide (CdS). In this case, the buffer layer 230 is an N-type semiconductor layer, and the light absorbing layer 220 is a P-type semiconductor layer. Accordingly, the light absorbing layer 220 and the buffer layer 230 form a PN junction.

The high resistance buffer layer 240 may further includes a ZnO layer formed on the CdS layer through a sputtering process employing a ZnO target. The high resistance buffer layer 240 may be provided in the form of a transparent layer on the buffer layer 230.

For example, the high resistance buffer layer 240 may include one of indium tin oxide (ITO), zinc oxide (ZnO), and intrinsic zinc oxide (i-ZnO). The buffer layer 230 and the high resistance buffer layer 240 are interposed between the light absorbing layer 220 and a front electrode layer 250 that is formed in the following process.

In other words, since the light absorbing layer 230 and the front electrode 250 have great difference in a lattice constant and an energy band gap, the buffer layer 230 and the high resistance buffer layer 240 having a band gap placed between the band gaps of the light absorbing layer 230 and the front electrode layer 250 are interposed between the light absorbing layer 230 and the front electrode layer 250, thereby forming superior junction between the light absorbing layer 130 and the front electrode.

According to the embodiment, two buffer layers 230 and 240 are formed on the light absorbing layer 220, but the embodiment is not limited thereto. In this case, only one buffer layer may be formed, or at least three layers may be formed.

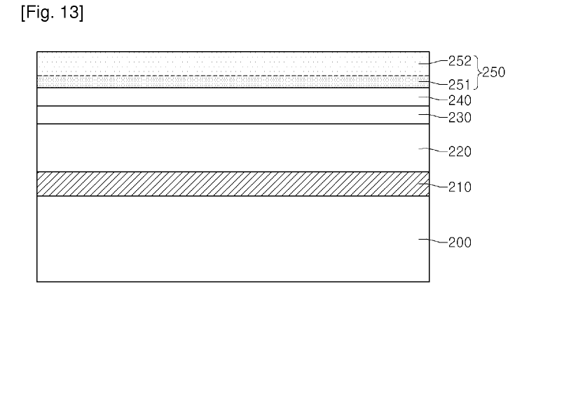

Referring to FIG. 13, a transparent conductive material is deposited on the high resistance buffer layer 240, thereby forming a front electrode layer 250. The front electrode layer 250 includes a transparent conductive layer or a window layer.

The front electrode layer 250 includes a first conductive layer 251 and a second conductive layer 252.

For example, the first and second conductive layers 251 and 252 may include ZnO or ITO doped with impurities such as aluminum (Al), alumina (Al₂O₃), magnesium (Mg), and gallium (Ga).

The first conductive layer 251 is formed on the high resistance buffer layer 240, and the second conductive layer 252 is formed on the first conductive layer 251.

The grain size of the first conductive layer 251 may be smaller than the grain size of the second conductive layer 251. In other words, the first conductive layer 251 may include crystalline particles at high density per unit area. Accordingly, the first conductive layer 251 may act as a diffusion barrier.

In other words, when the second conductive layer 252 is formed, the first conductive layer 251 can prevent conductive impurities contained in the second conductive layer 252 from being diffused into lower layers 220, 230, and 240.

The first conductive layer 251 may have a thickness corresponding to about 5% to about 40% of the thickness of the front electrode layer 250. For example, the first conductive layer 251 may have a thickness in the range of about 25 nm to about 600 nm. In more detail, the first conductive layer 251 may have the thickness of about 100 nm to about 300 nm.

The second conductive layer 252 has a thickness corresponding to about 60% to about 95% of the thickness of the front electrode layer 250. For example, the thickness of the second conductive layer 252 may be in the range of about 300 nm to about 1475 nm.

The first and second conductive layers 251 and 252 form a PN junction with the light absorbing layer 220. Since the first and second conductive layers 251 and 252 act as a transparent electrode at a front surface of the solar cell, the first and second conductive layers 251 and 252 include ZnO representing high light transmittance and high electrical conductivity.

For example, the first and second conductive layers 251 and 252 may be formed by using Al doped ZnO through a sputtering process. Accordingly, the first and second conductive layers 251 and 252 may have low surface resistance and high light transmittance.

The first and second conductive layers 251 and 252 may be formed through sputtering processes that are continuously performed. The first conductive layer 251 is formed through a first sputtering process of lower power and higher pressure, and the second conductive layer 252 may be formed through a second sputtering process of higher power and lower pressure.

In other words, the first and second conductive layers 251 and 252 may be continuously formed by changing process conditions in the same sputtering chamber.

For example, the first sputtering process to form the first conductive layer 251 may be performed with power of about 0.8 kW/cm² to about 1.1 kW/cm² at a process pressure of about 5 mtorr to about 8 mtorr while applying Ar gas at a flow rate of about 100 sccm to about 200 sccm. In this case, the grain size of the first conductive layer 251 may be in the range of about 50 nm to about 300 nm.

Crystalline constituting the first conductive layer 251 has small grain sizes due to the low power of the first sputtering process, and may be deposited on the high resistance buffer layer 240 in the form of a dense film due to high pressure. Accordingly, the first conductive layer 251 is formed at high density, thereby improving adhesion strength with lower and upper thin films.

In addition, the first conductive layer 251 prevents leakage current to improve the electrical characteristic of a device. This is because the first conductive layer 251 has a dense film quality to act as a barrier layer to prevent Al ions from being diffused into a lower layer when the second conductive layer 252 is formed.

After the first conductive layer 251 has been formed through the first sputtering process, a second sputtering process is formed. For example, the second sputtering process may be performed with power of 3.1 kW/cm² to 3.9 kW/cm² at a process pressure of 1 mtorr to 3 mtorr while applying Ar gas at a flow rate of 100 sccm to 200 sccm. In this case, the second conductive layer 252 may have a grain size of about 500 nm to about 1500 nm.

Crystalline constituting the second conductive layer 252 has a great grain size due to high power of the second sputtering process, and a deposition rate of the second conductive layer 252 is increased due to a low pressure, so that the second conductive layer 252 can be formed at a desired thickness.

Accordingly, the conductivity and the transmittance of the second conductive layer 252 can be improved.

Since the first conductive layer 251 is provided in the form of a dense film, the first conductive layer 251 can prevent Al ions from being diffused into a lower film when the second conductive layer 252 is formed, so that the electrical characteristic of a device can be improved.

In particular, the first and second conductive layers 251 and 252 may be formed at a temperature in the range of about 100° C. to about 150° C. This is because the first conductive layer 251 is formed with high and low power to have a dense film quality, so that the first conductive layer 251 can prevent Al ions from being diffused. Accordingly, the crystalline, conductivity, and transmittance of the second conductive layer 252 can be improved.

The first and second conductive layers 251 and 252 include the same material, and the adhesion strength therebetween can be improved.

The first and second conductive layers 251 and 252 can be formed by using one target without the variation in the Al doping density of Al doped ZnO that is a target material of the first and second sputtering processes. In other words, since the first conductive layer 251 acting as a barrier may be formed by changing only a process condition without an additional process, the productivity of a device can be improved.

Since the first conductive layer 251 can prevent Al ions from being diffused, the thickness of the high resistance buffer layer 240 can be minimized. Accordingly, the transmittance of light to the light absorbing layer 230 can be improved.

In addition, the loss of the line resistance can be prevented by the first conductive layer 251, and the whole thickness of the front electrode layer 250 can be lowered, so that the light transmittance can be improved.

Meanwhile, similarly, the second step of the embodiment is applicable to a device having a problem in the diffusion of a film containing a predetermined element. In other words, a barrier layer is formed on an initial interface surface by changing deposition conditions (e.g., power and pressure), so that the diffusion can be prevented.

Although the exemplary embodiments have been described, it is understood that the present invention should not be limited to these exemplary embodiments but various changes and modifications can be made by one ordinary skilled in the art within the spirit and scope of the present invention as hereinafter claimed.

TABLE 1
<Experimental Example 1>

| | | | | Surface | Trans- |
|---|---|---|---|---|---|
| | process | Process- | Thick- | resist- | mit- |
| | pressure | Temperature | ness | ance | tance |
| power | (mTorr) | (° C.) | (nm) | (Ω/□) | (%) |
| Cathode1: | 3 | roomTemperature | 500 | 16 | 87.4 |
| 1 kWCathode2: | | | | | |
| 4 kW | | | | | |

TABLE 2
<Experimental Example 2>

| | process | Process- | Thick- | Surface | Trans- |
|---|---|---|---|---|---|
| | pressure | Temperature | ness | resistance | mittance |
| power | (mTorr) | (° C.) | (nm) | (Ω/□) | (%) |
| Cathode1: | 3 | 150 | 500 | 13 | 88.6 |
| 1 kWCathode2: | | | | | |
| 4 kW | | | | | |

In experimental examples 1 and 2, the first and second cathodes to receive different power are arranged together. The substrate repeatedly moves to the Cathode 1 and the Cathode 2. The front electrode layer is formed through this sputtering process. However, in the case of experimental example 1, the front electrode layer is formed at a room temperature. In the case of the second experimental example, the front electrode layer is formed at a temperature of 150° C.

According to a scheme in which the same power is applied to the cathodes as shown in the comparative example, a high-temperature process (150° C.) is required in order to ensure desired surface resistance and transmittance. However, as shown in experimental example 1, lower surface resistance and high transmittance can be obtained at the normal temperature.

The improvement of characteristics in experimental Example 2 may result from the temperature.

TABLE 3
<Comparative Example>

| | process | | Thick- | Surface | Trans- |
|---|---|---|---|---|---|
| | pressure | ProcessTemperature | ness | resistance | mittance |
| power | (mTorr) | (° C.) | (nm) | (Ω/□) | (%) |
| 4 kW | 3 | 150 | 500 | 20 | 85 |

In the case of the comparative example, cathodes to receive predetermined power are arranged, and the front electrode layer is formed due to the high pressure and the high temperature.

As described through the above experimental examples, the rear electrode layer according to the present embodiment can satisfy adhesion strength and surface resistance through one sputtering process. In addition, the rear electrode layer is fabricated through one sputtering process, so that efficiency can be improved.

### INDUSTRIAL APPLICABILITY

The solar cell according to the embodiment is applicable to photovoltaic fields.

1. A solar cell comprising:
a substrate;
a rear electrode layer provided on the substrate;
a light absorbing layer provided on the rear electrode layer; and
a front electrode layer provided on the light absorbing layer, wherein the front electrode layer includes:
a first conductive layer provided on the light absorbing layer; and
a second conductive layer provided on the first conductive layer.

2. The solar cell of claim 1, wherein the first and second conductive layers include identical material, and have grain sizes different from each other.

3. The solar cell of claim 2, wherein the front electrode layer includes a third conductive layer provided on the second conductive layer.

4. The solar cell of claim 3, wherein the second conductive layer includes material identical to material of the third conductive layer, and has a grain size different from a grain size of the third conductive layer.

5. The solar cell of claim 4, wherein the front electrode layer includes a fourth conductive layer provided on the third conductive layer, and wherein the third and fourth conductive layers include identical material, and have grain sizes different from each other.

6. The solar cell of claim 5, wherein the grain size of the second conductive layer corresponds to the grain size of the fourth conductive layer, and
wherein the grain size of the first conductive layer corresponds to the grain size of the third conductive layer.

7. The solar cell of claim 2, wherein the first conductive layer has the grain size of about 15 nm to about 20 nm, and the second conductive layer has the grain size of about 30 nm to about 40 nm.

8. The solar cell of claim 1, wherein the first conductive layer has a thickness corresponding to 5% to 40% of a thickness of the front electrode layer, and
wherein the second conductive layer has a thickness corresponding to 60% to 95% of a thickness of the front electrode layer.

9. The solar cell of claim 1, wherein the second conductive layer has a thickness of about 300 nm to about 1475 nm.

10. A solar cell comprising:
a substrate;
a rear electrode layer provided on the substrate;
a light absorbing layer provided on the rear electrode layer; and
a plurality of conductive layers provided on the light absorbing layer,
wherein the conductive layers include identical material, and adjacent conductive layers have grain sizes different from each other.

11. The solar cell of claim 10, wherein three to ten conductive layers are provided.

12. The solar cell of claim 10, wherein the adjacent conductive layers have refractive indexes different from each other.

13. A method of fabricating a solar cell, the method comprising:
forming a rear electrode layer on a substrate;
forming a light absorbing layer on the rear electrode layer;
forming a first conductive layer on the light absorbing layer using first power; and
forming a second conductive layer on the first conductive layer using second power.

14. The method of claim 13, further comprising forming a third conductive layer on the second conductive layer using third power.

15. The method of claim 14, further comprising forming a fourth conductive layer on the third conductive layer using fourth power.

16. The method of claim 15, wherein the first power corresponds to the third power, and the second power corresponds to the fourth power.

17. The method of claim 13, wherein a target material used to form the first conductive layer is identical to a target material used to form the second conductive layer.

18. The method of claim 13, wherein the forming of the first conductive layer and the forming of the second conductive layer are performed through a sputtering process using Al doped ZnO, and
wherein the first power is in a range of about 1 kW/cm² to about 2 kW/cm², and the second power is in a range of about 4 kW/cm² to about 10 kW/cm².

19. The method of claim 13, wherein the forming of the first conductive layer is performed at first pressure, and the forming of the second conductive layer is performed at second pressure lower than the first pressure.

20. The method of claim 13, wherein the first power is in a range of about 0.8 kW/cm² to about 1.1 kW/cm²,
wherein the first conductive layer is formed at a pressure of about 5 mtorr to about 8 mtorr,
wherein the second power is in a range of about 3.1 kW/cm² to about 3.9 kW/cm², and
wherein the second conductive layer is formed at a pressure of about 1 mtorr to about 3 mtorr.
